(19) United States
(12) Patent Application Publication
(10) Pub. No.: US 2020/0204157 A1
(43) Pub. Date: Jun. 25, 2020

(54) FRONT END MODULE

(71) Applicant: SAMSUNG ELECTRO-MECHANICS CO., LTD., Suwon-si (KR)

(72) Inventors: Tah Joon PARK, Suwon-si (KR); Won Kyu JEUNG, Suwon-si (KR); Sung Tae KIM, Suwon-si (KR)

(73) Assignee: SAMSUNG ELECTRO-MECHANICS CO., LTD., Suwon-si (KR)

(21) Appl. No.: 16/416,505

(22) Filed: May 20, 2019

(30) Foreign Application Priority Data
Dec. 21, 2018 (KR) 10-2018-0167660

(51) Int. Cl. H03H 9/70; H03H 9/10; H03H 9/56

(52) U.S. Cl. CPC H03H 9/703; H03H 9/105; H03H 9/568; H03H 9/564; H03H 9/562

(57) ABSTRACT

A front end module includes a filter portion including filters each including at least one bulk-acoustic wave resonator including a first electrode, a piezoelectric layer, and a second electrode stacked in order, and the filters each have a different allocated passband such that a frequency band of each passband overlaps a portion of a frequency band of an adjacent passband; and a switch portion to be selectively connected to the filters to form a path of a wireless frequency signal.

### CROSS-REFERENCE TO RELATED APPLICATION

This application claims the benefit under 35 USC 119(a) of Korean Patent Application No. 10-2018-0167660 filed on Dec. 21, 2018 in the Korean Intellectual Property Office, the entire disclosure of which is herein incorporated by reference for all purposes.

### BACKGROUND

The following description relates to a front end module.

With the rapid development of mobile communication devices, chemical and biological devices, and the like, demand for a small-sized lightweight filter, an oscillator, a resonant element, an acoustic resonant mass sensor, and the like, used in such devices, has increased.

Generally, a film bulk acoustic resonator (FBAR) has been used for implementing a small-sized lightweight filter, an oscillator, a resonant element, an acoustic resonant mass sensor, and the like. A film bulk acoustic resonator may be mass produced at significantly low cost, and a micro-sized film bulk acoustic resonator may be implemented. Also, a film bulk acoustic resonator may implement a high quality factor (Q), one of main properties of a filter, and may be used in a variety of GHz frequency bands.

Generally, a bulk-acoustic wave resonator may include a resonance portion implemented by stacking a first electrode, a piezoelectric layer, and a second electrode on a substrate. With regard to operational principles of a bulk-acoustic wave resonator, an electric field is induced in a piezoelectric layer by electrical energy applied to first and second electrodes, and a piezoelectric effect may occur in the piezoelectric layer by the induced electric field such that a resonator may vibrate in a certain direction. As a result, bulk acoustic waves may be generated in the same direction as the vibration direction, and resonance may occur.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, a front end module includes a filter portion including filters each including at least one bulk-acoustic wave resonator including a first electrode, a piezoelectric layer, and a second electrode stacked in order, and each of the filters have a different allocated passband such that a frequency band of each passband overlaps a portion of a frequency band of an adjacent passband; and a switch portion to be selectively connected to the filters to a path of a wireless frequency signal.

An overlapping bandwidth between adjacent passbands may be determined based on a bandwidth of one of a plurality of channels supported by the filters.

The overlapping bandwidth between adjacent passbands may be determined based on a bandwidth of a channel, among the plurality of channels, having a maximum bandwidth.

Each of the filters may include a band pass filter.

A bandwidth of each of the passbands may be the same.

The switch portion may include a first switch disposed between a first end of each of the filters and an antenna; and a second switch disposed between a second end of each of the filters and a wireless frequency signal processing device.

The at least one bulk-acoustic wave resonator may be connected in at least one of a ladder type manner and a lattice type manner.

In another general aspect, a front ends module includes filters each including at least one bulk-acoustic wave resonator including a first electrode, a piezoelectric layer, and a second electrode stacked in order, each of the filters having a different allocated passband; and a switch portion to selectively connect the filters to form a path of a wireless frequency signal. The passbands include a first passband having a first frequency band and a second passband adjacent to the first passband and having a second frequency band higher than the first frequency band, and an upper limit frequency of the first passband is higher than a lower limit frequency of the second passband.

An overlapping bandwidth between the first passband and the second passband may be determined based on a bandwidth of one of a plurality of channels supported by filters.

The overlapping bandwidth between the first passband and the second passband may be determined based on a bandwidth of a channel, among the plurality of channels, having a maximum bandwidth.

Each of the filters may include a band pass filter.

The filters may include a first filter having the first passband allocated thereto and a second filter having the second passband allocated thereto.

The front end module may include a third filter having a third passband allocated thereto, and the third passband may have a third frequency band higher than the second frequency band.

An upper limit frequency of the second passband may be higher than a lower limit frequency of the third passband.

The filters may be implemented as a one-chip.

The at least one bulk-acoustic wave resonator may be connected in at least one of a ladder type manner and a lattice type manner.

The switch portion may include a first switch and a second switch, the first switch and the second switch may be connected to the first filter at an operational timing of the first filter, the first switch and the second switch may be connected to the second filter at an operational timing of the second filter, and the first switch and the second switch may be connected to the third filter at an operational timing of the second filter.

Other features and aspects will be apparent from the following detailed description, the drawings, and the claims.

### BRIEF DESCRIPTION OF DRAWINGS

FIG. 1 is a cross-sectional diagram illustrating a filter according to an example.

FIG. 2 is a circuit diagram illustrating a filter including a bulk-acoustic wave resonator according to an example.

FIG. 3 is graphs illustrating a frequency response of a filter.

FIG. 4 is a circuit diagram illustrating a front end module according to an example.

FIG. 5 is a circuit diagram illustrating a front end module according to an example.

FIG. 6 is graphs illustrating passbands allocated to a plurality of filters of a front end module.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that would be well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Herein, it is noted that use of the term “may” with respect to an example or embodiment, e.g., as to what an example or embodiment may include or implement, means that at least one example or embodiment exists in which such a feature is included or implemented while all examples and embodiments are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

Hereinafter, examples of the present disclosure will be described with reference to the attached drawings.

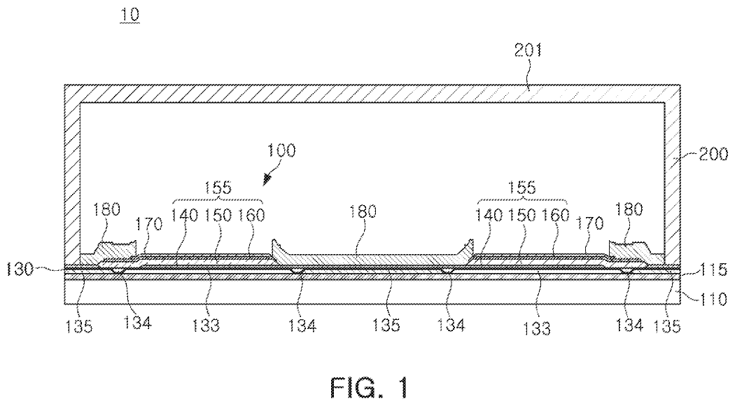

FIG. 1 is a cross-sectional diagram illustrating a filter according to an example.

Referring to FIG. 1, a filter 10 may include at least one bulk-acoustic wave resonator 100 and a cap 200. FIG. 1 illustrates the example in which the filter 10 includes two bulk-acoustic wave resonators 100, but the configuration of the filter 10 is not limited to two bulk-acoustic wave resonators 100. For example, the filter 10 may include a single bulk-acoustic wave resonator 100 or three or more bulk-acoustic wave resonators 100. The bulk-acoustic wave resonator 100 may be a film bulk acoustic resonator (FBAR).

The bulk-acoustic wave resonator 100 may include a stack structure including a plurality of films. The stack structure included in the bulk-acoustic wave resonator 100 may include a substrate 110, an insulating layer 115, an air cavity 133, a support portion 134, an auxiliary support portion 135, and a resonator 155 including a first electrode 140, a piezoelectric layer 150, and a second electrode 160, and may further include a protective layer 170 and a metal layer 180.

With regard to a manufacturing process of the bulk-acoustic wave resonator 100, a sacrificial layer may be formed on the insulating layer 115, and a pattern on which the support portion 134 is arranged may be prepared by partially removing the sacrificial layer. The auxiliary support portion 135 may be formed by a remaining sacrificial layer. A width of an upper surface of a pattern formed on the sacrificial layer may be greater than a width of a lower portion, and side surfaces connecting the upper surface and the lower surface may be inclined. After a pattern is formed on the sacrificial layer, a membrane 130 may be disposed on the insulating layer 115 externally exposed by the sacrificial layer and the pattern. After the membrane 130 is formed, an etch stop material covering the membrane 130 and working as a base for the formation of the support portion 134 may be formed.

After the etch stop material is formed, one surface of the etch stop material may be planarized such that the membrane 130 disposed on an upper surface of the sacrificial layer may be externally exposed. A portion of the etch stop material may be removed in the planarization of one surface of the etch stop material, and after a portion of the etch stop material is removed, the support portion 134 may be formed by the etch stop material remaining in the pattern. As the result of the planarization of the etch stop material, one surface of the support portion 134 and one surface of the sacrificial layer may be approximately planar. The membrane 130 may work as a stop layer in the planarization process of the etch stop material.

The first electrode 140, the piezoelectric layer 150, and the second electrode 160, and so on, may be stacked, and the air cavity 133 may be formed through an etching process in which the sacrificial layer is etched and removed. As an example, the sacrificial layer may include polycrystalline silicon (poly-Si). The air cavity 133 may be disposed in a lower portion of the resonator 155 such that the resonator 155 including the first electrode 140, the piezoelectric layer 150, and the second electrode 160 may vibrate in a certain direction.

The substrate 110 may include a silicon substrate, and the insulating layer 115, which electrically isolates the resonator 155 from the substrate 110, may be arranged on an upper surface of the substrate 110. The insulating layer 115 may be formed of at least one element among silicon dioxide (SiO2), silicon nitride (Si3N4), aluminium oxide (Al2O3), and aluminum nitride (AlN), and may be formed on the substrate 110 through a chemical vapor deposition process, an RF magnetron sputtering process, or an evaporation process.

An etch stop layer may further be formed on the insulating layer 115. The etch stop layer may protect the substrate 110 and the insulating layer 115 from an etching process, and may work as a base for other layers deposited on the etch stop layer.

The air cavity 133 and the support portion 134 may be disposed on the insulating layer 115. The air cavity 133 may be formed by forming the sacrificial layer on the insulating layer 115, forming a pattern on which the support portion 134 is arranged on the sacrificial layer, stacking the first electrode 140, the piezoelectric layer 150, and the second electrode 160, and performing an etching process in which the sacrificial layer is etched and removed.

The air cavity 133 may be disposed in a lower portion of the resonator 155 such that the resonator 155 including the first electrode 140, the piezoelectric layer 150, and the second electrode 160 may vibrate in a certain direction. The support portion 134 may be disposed on one side of the air cavity 133.

A thickness of the support portion 134 may be the same as a thickness of the air cavity 133. Thus, upper surfaces provided by the air cavity 133 and the support portion 134 may be approximately planar (the upper edge of the air cavity 133 may be co-planar with an upper surface of the support portion 134, for example). In the example, the resonator 155 may be disposed on the planar surface on which a stepped portion is removed to resolve insertion loss and to improve attenuation properties of the bulk-acoustic wave resonator 100.

A cross-sectional surface of the support portion 134 may have an approximately trapezoid shape. For example, a width of an upper surface of the support portion 134 may be greater than a width of a lower portion, and side surfaces connecting the upper surface and the lower surface may be inclined. The support portion 134 may be formed of a material not etched during an etching process for removing the sacrificial layer. As an example, the sacrificial layer may be formed of a material the same as a material of the insulating layer 115. For example, the support portion 134 may be formed of one element between silicon dioxide (SiO2) and silicon nitride (Si3N4), or a combination thereof.

In the example, side surfaces of the support portion 134 may be configured to be inclined to prevent an abrupt stepped portion on a boundary between the support portion 134 and the sacrificial layer, and a width of a lower surface of the support portion 134 may be configured to be narrow to prevent a dishing. As an example, an angle formed by a lower surface and side surfaces of the support portion 134 may be 110° to 160°, and a width of a lower surface of the support portion 134 may be 2 μm to 30 μm.

The auxiliary support portion 135 may be arranged externally of the support portion 134. The auxiliary support portion 135 may be formed of a material the same as a material of the support portion 134, or may be formed of a material different from a material of the support portion 134. As an example, when the auxiliary support portion 135 is formed of a material different from a material of the support portion 134, the auxiliary support portion 135 may correspond to a remaining portion of the sacrificial layer on the insulating layer 115 after an etching process.

The resonator 155 may include the first electrode 140, the piezoelectric layer 150, and the second electrode 160. A common region in which the first electrode 140, the piezoelectric layer 150, and the second electrode 160 overlap in a vertical direction may be disposed in an upper portion of the air cavity 133. The first electrode 140 and the second electrode 160 may be formed of one element among gold (Au), titanium (Ti), tantalum (Ta), molybdenum (Mo), ruthenium (Ru), platinum (Pt), tungsten (W), aluminum (Al), iridium (Ir), and nickel (Ni), or alloys thereof. The piezoelectric layer 150 may be a portion generating a piezoelectric effect which converts electrical energy into mechanical energy formed as elastic waves, and zinc oxide (ZnO), aluminum nitride (AIN), doped aluminum nitride (AIN), lead zirconate titanate (PZT; PbZrTiO), quarts, and the like, may be used as a material of the piezoelectric layer 150. The doped aluminum nitride (AIN) may further include a rare earth metal, a transition metal, or an alkaline earth metal. As an example, the rare earth metal may include at least one element among scandium (Sc), erbium (Er), yttrium (Y), and lanthanum (La), and a content of the rare earth element may be 1 to 20 at %. The transition metal may include at least one element among hafnium (Hf), titanium (Ti), zirconium (Zr), tantalum (Ta), and niobium (Nb). The alkaline earth metal may include magnesium (Mg).

The membrane 130 may be formed a material which is not easily removed during the process of forming the cavity 133. For example, to form the cavity 133, when a halide-based etching gas such as fluorine (F), chlorine (CI), and the like, is used to remove a portion of the sacrificial layer, the membrane 130 may be formed of a material having relative low reactivity with the etching gas. For example, the membrane 130 may include at least one element between silicon dioxide (SiO2) and silicon nitride (Si3N4). The membrane 130 may also be formed of a dielectric layer including at least one element among magnesium oxide (MgO), zirconium oxide (ZrO2), aluminum nitride (AlN), lead zirconate titanate (PZT), gallium arsenide (GaAs), hafnium oxide (HfO2), aluminium oxide (Al2O3), titanium dioxide (TiO2), and zinc oxide (ZnO), or may be formed of a metal layer including at least one element among aluminum (Al), nickel (Ni), chromium (Cr), platinum (Pt), gallium (Ga), hafnium (Hf).

A seed layer formed of aluminum nitride (AlN) may be formed on the membrane 130. For example, the seed layer may be disposed between the membrane 130 and the first electrode 140. Alternatively, the seed layer may be formed of a dielectric material or a metal having an HCP structure besides aluminum nitride (AlN). When the seed layer is a metal, the seed layer may be formed of titanium (Ti), for example.

The protective layer 170 may be disposed on the second electrode 160, and may prevent the second electrode 160 from being externally exposed. The protective layer 170 may be formed of one insulating material among a silicon oxide-based material, a silicon nitride-based material, an aluminum nitride-based material, and an aluminum oxide-based material. The metal layer 180 may be formed on the externally exposed first electrode 140 and second electrode 160.

The resonator 155 may be divided into an active region and an inactive region. The active region of the resonator 155 may be a region vibrating in a certain direction and resonating due to a piezoelectric effect generated from the piezoelectric layer 150 when electrical energy such as a wireless frequency signal is applied to the first electrode 140 and the second electrode 160, and may be a region in which the first electrode 140, the piezoelectric layer 150, and the second electrode 160 overlap in a vertical direction in an upper portion of the air cavity 133. The inactive region of the resonator 155 may be a region which does not resonate for a piezoelectric effect even when electrical energy is applied to the first electrode 140 and second electrode 160, and may be an external region of the active region.

The resonator 155 may output a wireless frequency signal having a certain frequency using a piezoelectric effect. For example, the resonator 155 may output a wireless frequency signal having a resonance frequency corresponding to vibrations caused by the piezoelectric effect.

The cap 200 may be bonded to a stack structure included in a plurality of the bulk-acoustic wave resonators 100. The cap 200 may be formed as a cover including an internal space in which the plurality of bulk-acoustic wave resonators 100 are disposed. The cap 200 may have a hexahedral shape in which a lower surface is opened, and may accordingly include an upper portion and a plurality of lateral portions connected to the upper portion.

The cap 200 may include a receiving portion in a central region to receive the resonators 155 of the plurality of bulk-acoustic wave resonators 100. The stack structure may be in contact with the plurality of lateral portions in a bonding region, and the bonding region of the stack structure may be edges of the stack structure. The cap 200 may be bonded to the substrate 110 and be stacked on the substrate 110. Also, the cap 200 may be bonded to at least one of the protective layer 170, the membrane 130, the insulating layer 115, the first electrode 140, the piezoelectric layer 150, the second electrode 160, and the metal layer 180.

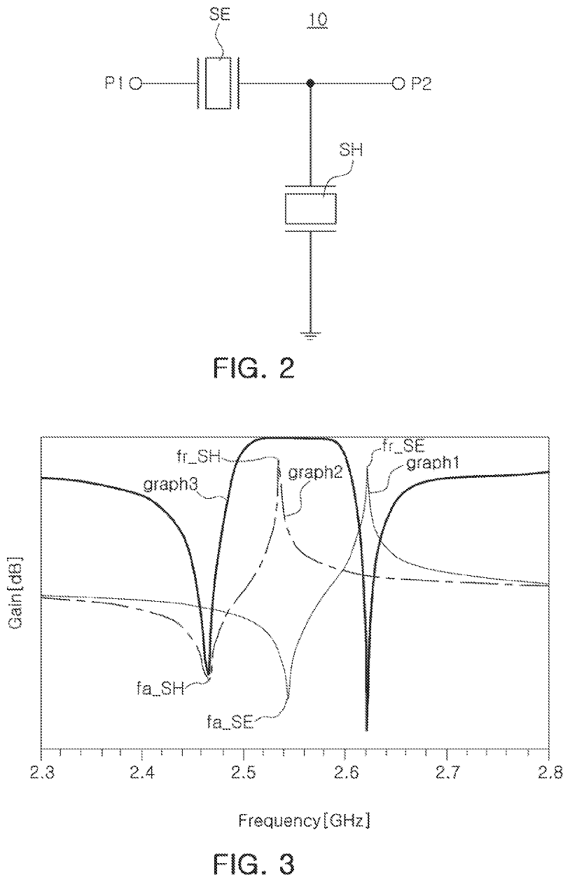

FIG. 2 is a circuit diagram illustrating a filter including a bulk-acoustic wave resonator according to an example. FIG. 3 is graphs illustrating a frequency response of a filter.

Referring to FIG. 2, a filter 10 may include a series resonator SE disposed between a first port P1 and a second port P2, and a shunt resonator SH disposed between the series resonator SE and a ground. The series resonator SE and the shunt resonator SH may correspond to a bulk-acoustic wave resonator illustrated in FIG. 1.

FIG. 2 illustrates a single series resonator SE and a single shunt resonator SH, but the filter is not limited to such a configuration. A plurality of series resonators SE may be disposed between the first port P1 and the second port P2, and a plurality of different shunt resonators SH may be disposed between each of the series resonators SE and a ground. FIG. 2 also illustrates an example in which the filter 10 may include the series resonator SE and the shunt resonator SH and may be implemented as a ladder type, but the filter is not limited to such a configuration. For example, the filter 10 may be implemented as a lattice type.

Referring to FIG. 3, a first graph (Graph 1) represents a frequency response (Z, impedance) obtained by using the series resonator SE, a second graph (Graph 2) represents a frequency response (Z, impedance) obtained by using the shunt resonator SH, and a third graph (Graph 3) represents a frequency response (S-parameter) obtained by using the filter including the series resonator SE and the shunt resonator SH.

A frequency response obtained by using the series resonator SE may have a resonance frequency (fr_{_}SE) and an antiresonance frequency (fa_{_}SE), and a frequency response obtained by using the shunt resonator SH may have a resonance frequency (fr_{_}SH) and an antiresonance frequency (fa_{_}SH).

Referring to the frequency response of the filter, a passband and a bandwidth of the filter may be determined based on the antiresonance frequency (fa_{_}SE) of the series resonator SE and the resonance frequency (fr_{_}SH) of the shunt resonator SH.

It has been expected that fifth generation (5G) communications may connect a greater number of devices with each other efficiently by transmitting higher capacity of data at a faster data transmission speed compared to long term evolution (LTE) communications.

A bandwidth of a frequency used in the 5G communications may be several hundreds of MHz, which is broader than previous standards, but a bandwidth actually allocated in each channel may be 100 MHz at maximum, which is relatively small. As an overall bandwidth has become broader, and a width between channels has decreased, there has been demand for a filter having high performance broadband properties and improved attenuation properties.

In the case of an n41 (2.496˜2.690 GHz) band having the broadest bandwidth among LTE communication bands, a BW/fc (bandwidth/center frequency) may be 0.0748, in the case of an n77 (3.3˜4.2 GHz) band of 5G communications, BW/fc may be 0.24, and in the case of an n79 (4.4˜5.0 GHz) band of 5G communications, BW/fc may be 0.128. When the n41 (2.496˜2.690 GHz) band, the n77 (3.3˜4.2 GHz) band, and the n79 (4.4˜5.0 GHz) band are compared with one another, the n77 (3.3˜4.2 GHz) band and the n79 (4.4˜5.0 GHz) band of 5G communications may need to have higher broadband properties than that of the n41 (2.496˜2.690 GHz) band of LTE communications.

The more the broadband properties are required, the higher the piezoelectric coupling coefficient (kt2) may need to be increased, but there may be a limitation in increasing concentration of impurities of a piezoelectric layer of a bulk-acoustic wave resonator to increase the piezoelectric coupling coefficient. Thus, when manufacturing a broadband filter, performance may inevitably be deteriorated.

In the front end module in the examples disclosed herein, a plurality of filters having different passbands may be combined to support an overall passband of 5G mobile communications, and the plurality of filters having different passbands may be selectively connected such that the plurality of filters may respectively take charge of passbands of designed channels, thereby implementing high performance broadband properties and improved attenuation properties.

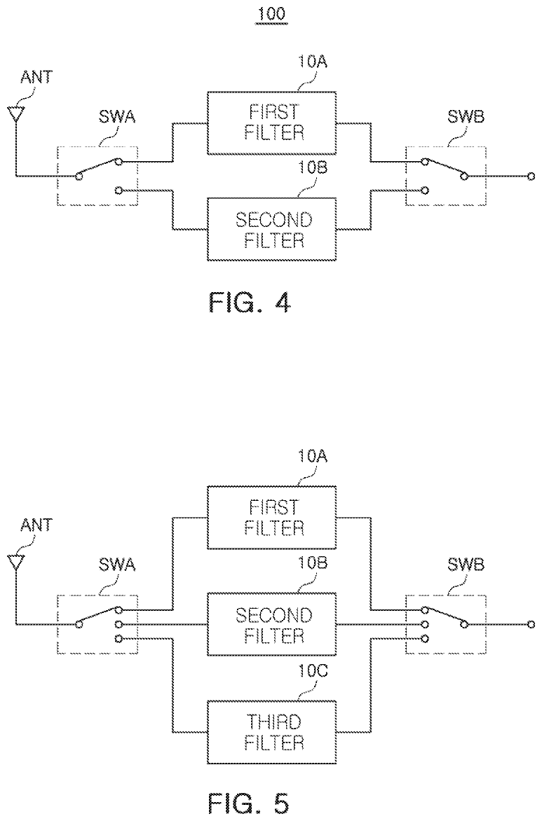

FIG. 4 is a circuit diagram illustrating a front end module according to an example.

Referring to FIG. 4, a front end module may include a first filter 10A and a second filter 10B, and may include a first switch SWA and a second switch SWB selectively connected to the first filter 10A and the second filter 10B.

The first filter 10A and a second filter 10B may be included in a filter portion, and the first filter 10A and the second filter 10B each may include a band pass filter. As an example, the first filter 10A and the second filter 10B may include the filter 10 illustrated in FIG. 2, and accordingly, the first filter 10A and the second filter 10B each may include at least one bulk-acoustic wave resonator. The first filter 10A and the second filter 10B may be implemented by a one-chip.

The first filter 10A and the second filter 10B may have different passbands. As an example, a passband of the first filter 10A may be formed in a lower frequency band than a frequency band of a passband of the second filter 10B.

A frequency band of a passband of the first filter 10A and a frequency band of a passband of the second filter 10B may partially overlap. Accordingly, an upper limit frequency of the first filter 10A may be positioned in a higher frequency band than a lower limit frequency of the second filter 10B.

An overlapping bandwidth between a passband of the first filter 10A and a passband of the second filter 10B may be determined based on bandwidths of a plurality of channels supported by the first filter 10A and the second filter 10B.

For example, when it is assumed that the first filter 10A and the second filter 10B have the n77 (3.3˜4.2 GHz) band of 5G generation communications allocated thereto, n77 (3.3˜4.2 GHz) band may have a plurality of channels having various bandwidths. For example, the n77 (3.3˜4.2 GHz) band may have channels having various bandwidths such as 10 MHz, 20 MHz, 40 MHz, 50 MHz, 60 MHz, 80 MHz, 100 MHz, and the like.

An overlapping bandwidth between a passband of the first filter 10A and a passband of the second filter 10B may be determined based on a bandwidth of one of a plurality of channels having various bandwidths. As an example, an overlapping bandwidth between a passband of the first filter 10A and a passband of the second filter 10B may be determined based on a channel having a maximum bandwidth among a plurality of channels supported by the first filter 10A and the second filter 10B. For example, the overlapping bandwidth between a passband of the first filter 10A and a passband of the second filter 10B may be equal to or greater than a bandwidth of the channel having a maximum bandwidth.

By determining an overlapping bandwidth between a passband of the first filter 10A and a passband of the second filter 10B based on a bandwidth of a channel having a maximum bandwidth, even when the first filter 10A and the second filter 10B selectively operate, the channels may be stably supported.

A bandwidth of a passband of the first filter 10A and a bandwidth of a passband of the second filter 10B may be configured to be the same, or may be configured to be different from each other.

The first switch SWA and the second switch SWB may be included in a switch portion. One end of the first switch SWA may be connected to an antenna, and the other end may be connected to the first filter 10A and the second filter 10B. One end of the second switch SWB may be connected to a wireless frequency signal processing device such as a low noise amplifier (LNA), an RF IC, and the like, and the other end may be connected to the first filter 10A and the second filter 10B.

The first switch SWA and the second switch SWB may be selectively connected to the first filter 10A and the second filter 10B, and may form a path of a wireless frequency signal. The first switch SWA and the second switch SWB may be connected to one filter between the first filter 10A and the second filter 10B. As an example, at an operational timing of the first filter 10A, the first switch SWA and the second switch SWB may be connected to the first filter 10A, and at an operational timing of the second filter 10B, the first switch SWA and the second switch SWB may be connected to the second filter 10B.

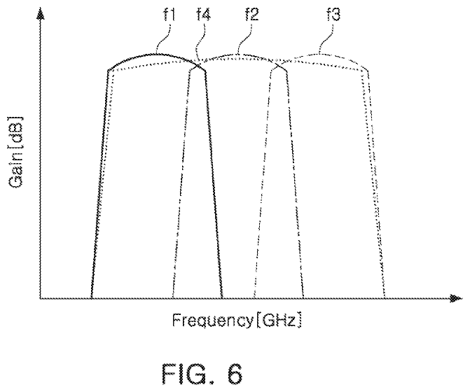

FIG. 5 is a circuit diagram illustrating a front end module according to an example. FIG. 6 is graphs illustrating passbands allocated to a plurality of filters of a front end module. The front end module illustrated in FIG. 5 is similar to the front end module illustrated in FIG. 4, and thus, overlapping descriptions will not be repeated, and differences will be described.

Referring to FIG. 5, a front end module may include a first filter 10A, a second filter 10B, and a third filter 100, and may further include a first switch SWA and a second switch SWB selectively connected to the first filter 10A, the second filter 10B, and the third filter 10C.

The first filter 10A, the second filter 10B, and the third filter 10C may be included in a filter portion, and the first filter 10A, the second filter 10B, and the third filter 10C each may include a band pass filter. As an example, the first filter 10A, the second filter 10B, and the third filter 10C may include the filter 10 illustrated in FIG. 2, and accordingly, the first filter 10A, the second filter 10B, and the third filter 10C each may include at least one bulk-acoustic wave resonator. The first filter 10A, the second filter 10B, and the third filter 10C may be implemented by a one-chip.

The first filter 10A, the second filter 10B, and the third filter 100 may have different passbands. Referring to a frequency response f1 obtained by using the first filter 10A, a frequency response f2 obtained by using the second filter 10B, and a frequency response f3 obtained by using the third filter 10C illustrated in FIG. 6, a passband of the first filter 10A may be formed in a lower frequency band than a passband of the second filter 10B, and a passband of the second filter 10B may be formed in a lower frequency band than a passband of the third filter 100. A frequency response f4 of an overall passband of 5G mobile communications may be covered by the frequency response f1 obtained by using the first filter 10A, the frequency response f2 obtained by using the second filter 10B, and the frequency response f3 obtained by using the third filter 100, as illustrated in FIG. 6.

A frequency band of a passband of the first filter 10A and a frequency of a passband of the second filter 10B may partially overlap, and a frequency band of a passband of the second filter 10B and a frequency band of a passband of the third filter 10C may partially overlap. Thus, an upper limit frequency of the first filter 10A may be positioned in a higher frequency band than a lower limit frequency of the second filter 10B, and an upper limit frequency of the second filter 10B may be positioned in a higher frequency band than a lower limit frequency of the third filter 10C.

An overlapping bandwidth between a passband of the first filter 10A and a passband of the second filter 10B, and an overlapping bandwidth between a passband of the second filter 10B and a passband of the third filter 10C may be determined based on bandwidths of a plurality of channels supported by the first filter 10A, the second filter 10B, and the third filter 10C.

For example, when it is assumed that the first filter 10A, the second filter 10B, and the third filter 10C have an n77 (3.318 4.2 GHz) band of 5G communications allocated thereto, the n77 (3.3˜4.2 GHz) band may have a plurality of channels having various bandwidths. For example, the n77 (3.3˜4.2 GHz) band may have channels having various bandwidths as 10 MHz, 20 MHz, 40 MHz, 50 MHz, 60 MHz, 80 MHz, 100 MHz, and the like.

An overlapping bandwidth between a passband of the first filter 10A and a passband of the second filter 10B, and an overlapping bandwidth between a passband of the second filter 10B and a passband of the third filter 100 may be determined based on a bandwidth of one of a plurality of channels having various bandwidths. As an example, an overlapping bandwidth between a passband of the first filter 10A and a passband of the second filter 10B, and an overlapping bandwidth between a passband of the second filter 10B and a passband of the third filter 10C may be determined based on a channel having a maximum bandwidth among a plurality of channels supported by the first filter 10A, the second filter 10B, and the third filter 100. For example, an overlapping bandwidth between a passband of the first filter 10A and a passband of the second filter 10B, and an overlapping bandwidth between a passband of the second filter 10B and a passband of the third filter 10C may be equal to or greater than a bandwidth of a channel having a maximum bandwidth.

By determining an overlapping bandwidth between a passband of the first filter 10A and a passband of the second filter 10B, and an overlapping bandwidth between a passband of the second filter 10B and a passband of the third filter 10C based on a bandwidth of a channel having a maximum bandwidth, even when the first filter 10A, the second filter 10B, and the third filter 10C selectively operate, the channels may be stably supported.

Bandwidths of passbands of the first filter 10A, the second filter 10B, and the third filter 10C may be configured to be the same, or may be configured to be different from one another.

The first switch SWA and the second switch SWB may be included in a switch portion. One end of the first switch SWA may be connected to an antenna, and the other end may be connected to the first filter 10A, the second filter 10B, and the third filter 10C. One end of the second filter 10B may be connected to a wireless frequency signal processing device such as a low noise amplifier (LNA), an RF IC, and the like, and the other end may be connected to the first filter 10A, the second filter 10B, and the third filter 10C.

The first switch SWA and the second switch SWB may be selectively connected to the first filter 10A, the second filter 10B, and the third filter 100 and may form a path of a wireless frequency signal. The first switch SWA and the second switch SWB may be connected to one filter among the first filter 10A, the second filter 10B, and the third filter 10C. As an example, at an operational timing of the first filter 10A, the first switch SWA and the second switch SWB may be connected to the first filter 10A, at an operational timing of the second filter 10B, the first switch SWA and the second switch SWB may be connected to the second filter 10B, and at an operational timing of the third filter 10C, the first switch SWA and the second switch SWB may be connected to the third filter 10C.

According to the aforementioned examples, a relatively broad frequency band of a next generation mobile communications may be covered while reducing interference between designed channels.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A front end module, comprising:
filters each comprising at least one bulk-acoustic wave resonator including a first electrode, a piezoelectric layer, and a second electrode stacked in order, each of the filters having a different allocated passband such that a frequency band of each passband overlaps a portion of a frequency band of an adjacent passband; and
a switch portion configured to be selectively connected to the filters to form a path of a wireless frequency signal.

2. The front end module of claim 1, wherein an overlapping bandwidth between adjacent passbands is determined based on a bandwidth of one of a plurality of channels supported by the filters.

3. The front end module of claim 2, wherein the overlapping bandwidth between adjacent passbands is determined based on a bandwidth of a channel, among the plurality of channels, having a maximum bandwidth.

4. The front end module of claim 1, wherein each of the filters includes a band pass filter.

5. The front end module of claim 1, wherein a bandwidth of each of the passbands is the same.

6. The front end module of claim 1, wherein the switch portion comprises:
a first switch disposed between a first end of each of the filters and an antenna; and
a second switch disposed between a second end of each of the filters and a wireless frequency signal processing device.

7. The front end module of claim 1, wherein the at least one bulk-acoustic wave resonator is connected in at least one of a ladder type manner and a lattice type manner.

8. A front end module, comprising:
filters each comprising at least one bulk-acoustic wave resonator including a first electrode, a piezoelectric layer, and a second electrode stacked in order, each of the filters having a different allocated passband; and
a switch portion configured to selectively connect the filters to form a path of a wireless frequency signal,
wherein the passbands include a first passband having a first frequency band and a second passband adjacent to the first passband and having a second frequency band higher than the first frequency band, and an upper limit frequency of the first passband is higher than a lower limit frequency of the second passband.

9. The front end module of claim 8, wherein an overlapping bandwidth between the first passband and the second passband is determined based on a bandwidth of one of a plurality of channels supported by filters.

10. The front end module of claim 9, wherein the overlapping bandwidth between the first passband and the second passband is determined based on a bandwidth of a channel, among the plurality of channels, having a maximum bandwidth.

11. The front end module of claim 8, wherein each of the filters includes a band pass filter.

12. The front end module of claim 8, wherein the filters include a first filter having the first passband allocated thereto and a second filter having the second passband allocated thereto.

13. The front end module of claim 12, further comprising a third filter having a third passband allocated thereto, the third passband having a third frequency band higher than the second frequency band.

14. The front end module of claim 13, wherein an upper limit frequency of the second passband is higher than a lower limit frequency of the third passband.

15. The front end module of claim 8, wherein the filters are implemented as a one-chip.

16. The front end module of claim 8, wherein the at least one bulk-acoustic wave resonator is connected in at least one of a ladder type manner and a lattice type manner.

17. The front end module of claim 8, wherein the switch portion comprises a first switch and a second switch, the first switch and the second switch are connected to the first filter at an operational timing of the first filter, the first switch and the second switch are connected to the second filter at an operational timing of the second filter, and the first switch and the second switch are connected to the third filter at an operational timing of the second filter.
